(19) United States
(12) Patent Application Publication
(10) Pub. No.: US 2025/0006880 A1
(43) Pub. Date: Jan. 2, 2025

(54) SEMICONDUCTOR LIGHT-EMITTING DEVICE

(71) Applicant: STANLEY ELECTRIC CO., LTD., Meguro-ku, Tokyo (JP)

(72) Inventors: Yoichi SHIMODA, Tokyo (JP); Daizo KAMBARA, Tokyo (JP); Yuji SHIGEEDA, Tokyo (JP); Koji ICHIKAWA, Tokyo (JP); Hiroyuki ISHIKO, Tokyo (JP)

(73) Assignee: STANLEY ELECTRIC CO., LTD., Meguro-ku, Tokyo (JP)

(21) Appl. No.: 18/707,606

(22) PCT Filed: Sep. 21, 2022
(86) PCT No.: PCT/JP2022/035194

§ 371 Date: May 6, 2024

(30) Foreign Application Priority Data
Nov. 24, 2021 (JP) 2021-189924

(51) Int. Cl. H01L 33/62; H01L 33/48

(52) U.S. Cl. CPC H01L 33/62; H01L 33/483

(57) ABSTRACT

A light-emitting device includes a first lead electrode and a second lead electrode, and a resin frame that covers an outer portion and a separation portion of the lead electrodes and has an opening portion that exposes the lead electrodes, and an LED. A protrusion provided in the first lead electrode is fitted into an enclosing portion provided in the second lead electrode to form a nested structure. Hollowed portions are provided in facing adjacent sides of the protrusion and the enclosing portion, and a region surrounded by the hollowed portion and the hollowed portion is filled with a part of a resin, thereby forming an anchor column.

### TECHNICAL FIELD

The present invention relates to a semiconductor light-emitting device, particularly to a semiconductor light-emitting device in which a lead frame is used as an electrode on which a light emitting element is placed.

### BACKGROUND ART

In the related art, a semiconductor device formed by sealing a semiconductor element inside is known. In addition, a semiconductor light-emitting device in which a semiconductor light emitting element is mounted on a substrate and the semiconductor light emitting element is hermetically sealed with a translucent member such as a resin or glass having a recessed portion is also well known.

A surface-mounted light-emitting device of Patent Literature 1 includes a light emitting element, a first resin molded body on which the light emitting element is placed, and a second resin molded body that covers the light emitting element. The first resin molded body is integrally molded to include a first lead for placing the light emitting element and a second lead electrically connected to the light emitting element.

The first lead and the second lead each have an uneven shape, thereby increasing a contact area with the first resin molded body. As a result, the first lead and the second lead are prevented from being detached from the first resin molded body (paragraph 0110 and FIG. 4 of Patent Literature 1).

### CITATION LIST

### Patent Literature

Patent Literature 1: Japanese Patent No. 4608294

### SUMMARY OF INVENTION

### Technical Problem

However, one wire connects an electrode of a light emitting element placed on a first lead and a second inner lead portion of the second lead. Therefore, in a case in which the first lead and the second lead are misaligned in a direction in which the first lead and the second lead are separated from each other, there is a problem that the wire is disconnected.

The present invention has been made in view of such circumstances, and an object of the present invention is to provide a semiconductor light-emitting device capable of preventing a misalignment of a lead electrode during solder mounting or the like.

### Solution to Problem

According to an embodiment of the present invention, there is provided a semiconductor light-emitting device including: a plurality of plate-shaped lead electrodes arranged side by side in a rectangular shape to be separated with a predetermined interval from each other; a frame consisting of a resin configured to cover an outer portion of the plurality of lead electrodes and a separation portion between the plurality of lead electrodes and having an opening portion that exposes the plurality of lead electrodes; and a light emitting element mounted on the plurality of lead electrodes exposed from the opening portion, in which the plurality of lead electrodes includes one lead electrode having a first adjacent side with a protruding portion provided in a portion separated from each other with the predetermined interval, and the other lead electrode having a second adjacent side with a recessed portion into which the protruding portion of the one lead electrode is fitted, the one lead electrode and the other lead electrode have a nested structure in which the protruding portion of the one lead electrode is fitted into the recessed portion of the other lead electrode, a hollowed portion having a predetermined shape extending over both the adjacent sides is provided in each of the first adjacent side and the second adjacent side, and a region surrounded by the hollowed portion of each of the one lead electrode and the other lead electrode is filled with a part of the resin forming the frame.

### BRIEF DESCRIPTION OF DRAWINGS

FIG. 1 is a perspective view of a light-emitting device according to a first embodiment of the present invention.

FIG. 2 is a top view of the light-emitting device according to the first embodiment of the present invention.

FIG. 3 is a top view of the light-emitting device in a state in which a coating member is removed.

FIG. 4 is a cross-sectional view taken along line A-A of the light-emitting device of FIG. 2.

FIG. 5 is a back view of the light-emitting device according to the first embodiment of the present invention.

FIG. 6A is a top view of a lead frame of a light-emitting device.

FIG. 6B is a back view of the lead frame of the light-emitting device.

FIG. 7 is an enlarged view of a region R of FIG. 6A.

FIG. 8A is a cross-sectional view taken along line B-B of the lead frame of FIG. 6A.

FIG. 8B is a cross-sectional view of a flip-chip type light emitting element (modified example).

FIG. 9 is a flowchart illustrating a manufacturing method of a light-emitting device of the first embodiment of the present invention.

FIG. 10A is a top view illustrating Step S11 of the manufacturing method.

FIG. 10B is a top view illustrating Step S12 of the manufacturing method.

FIG. 10C is a top view illustrating Step S13 of the manufacturing method.

FIG. 10D is a top view illustrating Step S14 of the manufacturing method.

FIG. 10E is a top view illustrating Step S15 of the manufacturing method.

FIG. 11 is a top view of the light-emitting device according to a second embodiment of the present invention.

FIG. 12 is a back view of the light-emitting device according to the second embodiment of the present invention.

FIG. 13 is a cross-sectional view taken along C-C line of the light-emitting device of FIG. 11.

FIG. 14 is an enlarged view of a region S of FIG. 13.

FIG. 15 is a flowchart illustrating a manufacturing method of a light-emitting device according to the second embodiment of the present invention.

### DESCRIPTION OF EMBODIMENTS

Hereinafter, preferred embodiments of the present invention will be described, but these embodiments may be appropriately modified and combined. In addition, in the following description and the accompanying drawings, substantially the same or equivalent parts will be described with the same reference numerals.

### First Embodiment

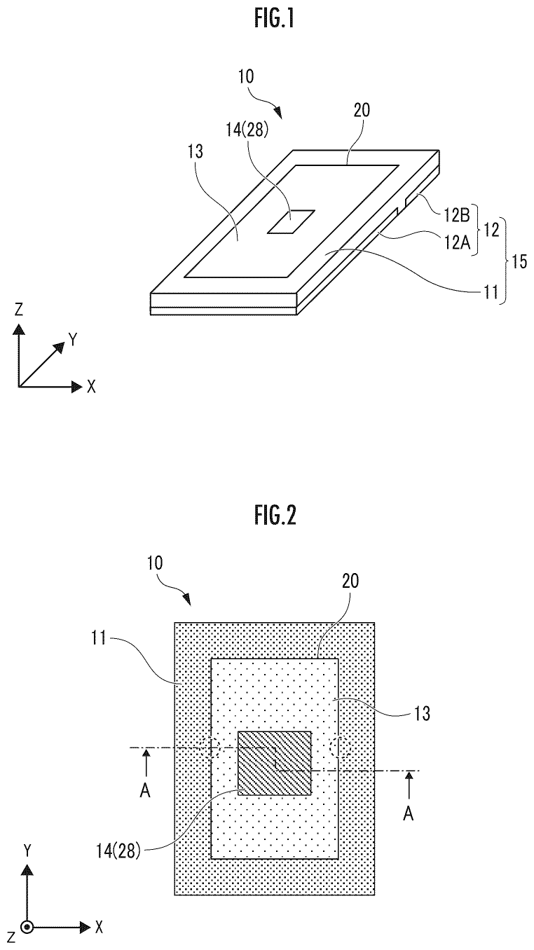

FIG. 1 is a perspective view schematically illustrating a light-emitting device 10 according to a first embodiment. FIG. 2 is a diagram illustrating a front surface side of the light-emitting device 10. A three-axis coordinate system is added to each drawing for convenience of indicating a correspondence direction between a plurality of drawings. A Z axis direction corresponds to an up-down direction of the light-emitting device 10, and an X axis direction and a Y axis direction correspond to a lateral direction and a longitudinal direction of a lead frame 12, respectively.

The light-emitting device 10 according to the present embodiment is a semiconductor light-emitting device that includes a substrate 15 including a frame 11 serving as a body of the light-emitting device 10 and a pair of lead frames 12, a light emitting diode (LED) 28 which is a semiconductor light emitting element and a phosphor plate 14 provided in an opening portion 20 of the substrate 15, and a reflective coating member 13 that embeds peripheries of the LED 28 and the phosphor plate 14.

In FIG. 1, the light-emitting device 10 (semiconductor light-emitting device) has a rectangular shape, and is composed of a substrate 15 including an upper rectangular frame 11 and a lower lead frame 12. The coating member 13 is provided inside the frame 11, and the phosphor plate 14 is exposed from a substantially central portion of the coating member 13.

The frame 11 is formed on the lead frame 12 of a thermosetting resin. The frame 11 is formed of a silicone resin and/or an epoxy resin and contains light reflective particles such as titanium oxide particles (hereinafter, referred to as a frame resin). The frame 11 may include a light absorbing material such as carbon black. In addition, the frame 11 has the opening portion 20 which is an inner region of the frame, and the LED 28 (lower portion of the phosphor plate 14) which is the semiconductor light-emitting device is mounted in the opening portion 20.

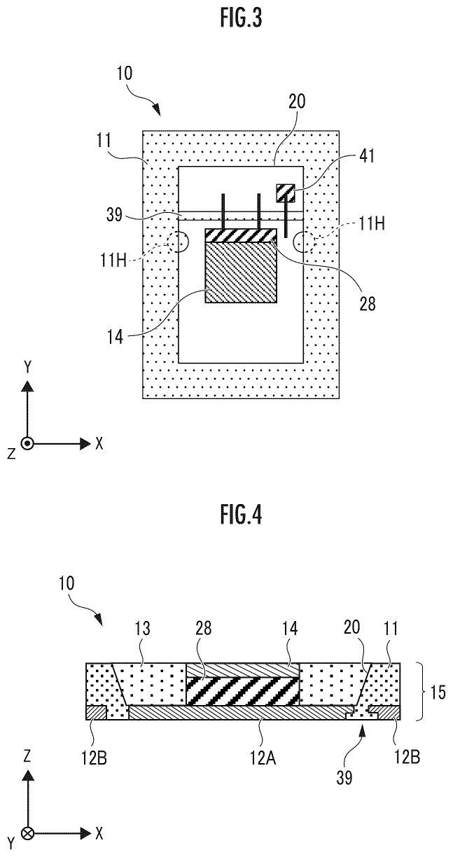

FIG. 3 is a top view schematically illustrating an inside of the opening portion 20 from the top view of the light-emitting device 10 illustrated in FIG. 2, excluding the coating member 13. In addition, FIG. 4 is a schematic cross-sectional view (free cross-sectional view) of a portion of the light-emitting device 10 illustrated in FIG. 2, which is cut along line A-A (one-dot chain line).

The lead frame 12 includes a lead electrode 12A (first electrode) and a lead electrode 12B (second electrode), which are plate-shaped electrodes having a thickness of 0.2 to 0.3 mm. The lead electrode 12A and the lead electrode 12B is formed of copper (Cu), and surfaces thereof are plated with nickel (Ni)/gold (Au). In a case where the surface is represented as Ni/Au, Ni indicates a first layer and Au indicates a second layer. The lead electrode 12A and the lead electrode 12B are arranged side by side to be separated from each other by a slit 39 (“separation portion” of the present invention) on substantially the same plane.

The LED 28 according to the present embodiment is, for example, a semiconductor light emitting element that emits blue light, but may be another element such as a surface emission type laser diode. More specifically, the lead electrode 12A is a cathode electrode, and the lead electrode 12B is an anode electrode. The n-electrode of the LED 28 is connected to and placed on the lead electrode 12A, and the p-electrode of the LED 28 is connected to the lead electrode 12B by a bonding wire.

As illustrated in FIG. 4, the phosphor plate 14 is provided on an upper surface side of the LED 28. A part of the blue light emitted upward from the LED 28 is wavelength-converted into, for example, yellow light in a case of passing through the phosphor plate 14. As a result, the emitted light from the light-emitting device 10 is white light which is a mixture of the transmitted blue light that is not wavelength-converted by the phosphor plate 14, and yellow light.

The phosphor plate 14 is not particularly limited, and various phosphors such as yttrium aluminum garnet (YAG), lutetium aluminum garnet (LuAG), gadolinium aluminum garnet (GYAG), α-sialon, β-sialon, SCASN, CASN, and KFS can be appropriately used. The phosphor plate 14 may be an optical element such as a translucent glass or a light distribution control plate. In this case, the emitted light from the light-emitting device 10 is the light emission color of the LED 28.

In the opening portion 20 of the frame 11, a space around the LED 28 and the phosphor plate 14 is filled with the coating member 13 which is a sealing resin or a covering resin. In addition, the surface (upper surface) of the phosphor plate 14 is exposed from the coating member 13. Examples of the coating member 13 include a light reflective resin in which titanium oxide particles and the like are contained in a silicone resin, but the present invention is not limited thereto.

The LED 28 and a protective element 41 which is a Zener diode are provided on the lead electrode 12A and the lead electrode 12B exposed from the opening portion 20. The protective element 41 need only be an element capable of preventing the overcurrent from flowing to the LED 28, and a varistor, a capacitor, a resistor, a light-receiving element, or the like may be used.

In addition, as illustrated in FIG. 3, in the opening portion 20 of the frame 11, anchor columns 11H are provided at positions symmetric with respect to the center line (“arrangement direction of lead electrodes” of the present invention) extending in the Y axis direction, one by one. The anchor column 11H is a portion formed of a region in which recessed portions provided in outer peripheral portions of the lead electrode 12A and the lead electrode 12B are disposed to face each other and filled with a frame resin, and is formed as a columnar resin body (details will be described below).

As illustrated in FIGS. 3 and 4, the substrate 15 has the opening portion 20 defined by the frame 11 and the lead electrodes 12A and 12B. The opening portion 20 has a shape of an inverted quadrangular pyramid having a rectangular bottom surface. Inside the substrate 15, the LED 28 is mounted on the lead electrode 12A, and the phosphor plate 14 is placed on the LED 28. In addition, peripheries of the LED 28 and the phosphor plate 14 are filled with the coating member 13.

An upper end portion of the lead frame 12 is filled with a frame resin. In addition, each end portion (only the right side in FIG. 4) of the lead electrode 12A and the lead electrode 12B on the back surface side has a step portion formed by half-etching (details will be described below). In the present specification, the “back surface side” of the lead electrode 12A and the lead electrode 12B refers to a lower surface side.

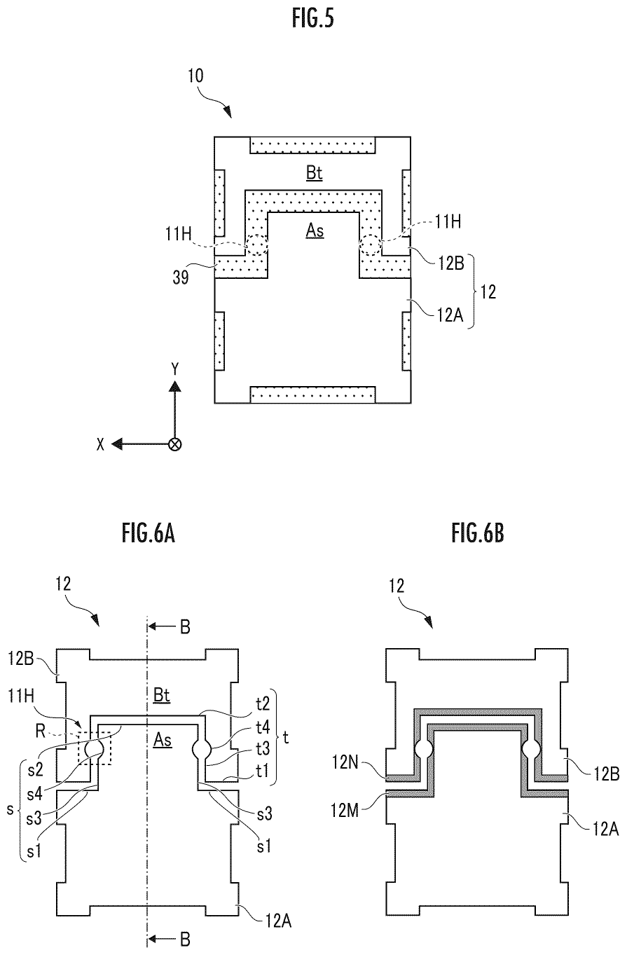

Next, the lead frame 12 will be described in detail. FIG. 5 is a diagram illustrating a back surface side of the light-emitting device 10. FIG. 6A is a diagram illustrating the upper surface side of the lead frame 12, and FIG. 6B is a diagram illustrating the lower surface side of the lead frame 12. In addition, FIG. 7 is an enlarged view of a region R surrounded by a broken line in FIG. 6A.

The lead frame 12 includes the lead electrode 12A (“one lead electrode” of the present invention) and the lead electrode 12B (“the other lead electrode” of the present invention), and a region between the lead electrode 12A and the lead electrode 12B is a slit 39. A width (gap in the X axis direction and gap in the Y axis direction) of the slit 39 is equal to the thickness of the lead electrodes 12A and 12B, and is, for example, about 0.2 to 0.3 mm.

As illustrated in FIGS. 5 and 6A, the lead electrode 12A has a protrusion As (“protruding portion” of the present invention) across the slit 39. In addition, the lead electrode 12B includes an enclosing portion Bt (recessed portion of the present invention). The protrusion As has a nested structure that is fitted into the enclosing portion Bt.

Specifically, the first adjacent side s on the side of the lead electrode 12A adjacent to the lead electrode 12B is defined by two base sides s1 reaching, from the outside of the lead electrode 12A, a base portion of the protrusion As that protrudes to the lead electrode 12B side, a top side s2 forming a top portion of the protrusion As, and two protruding sides s3 connecting the base sides s1 and the top side s2.

In addition, a second adjacent side t on the side of the lead electrode 12B adjacent to the lead electrode 12A is defined by two base sides t1 reaching, from the outside of the lead electrode 12B, an edge portion of the enclosing portion Bt that encloses the protrusion As of the lead electrode 12A, a bottom side t2 forming the bottom portion of the enclosing portion Bt, and two enclosing sides t3 connecting the base sides t1 and the bottom side t2.

It is preferable that the protruding side s3 and the enclosing side t3 are parallel to a B-B line which is the center line so that external stress acting on the lead electrode 12A and the lead electrode 12B is equivalent to each other. In addition, the base side s1 and the top side s2, and the bottom side t2 and the base side t1 are orthogonal to the B-B line so that the lead electrodes 12A and 12B can be easily formed.

It should be noted that the shape of the protrusion As of the lead electrode 12A and the shape of the enclosing portion Bt of the lead electrode 12B are not limited to the rectangular shape, and may include a trapezoidal shape or a partially circular shape. However, it is essential that each side constituting the protrusion As and the enclosing portion Bt extends in the Y-axis (long axis) direction.

The inside of the slit 39 is filled with the frame resin. In addition, the pair of anchor columns 11H (broken line portion) is provided in the slit 39 symmetrically with respect to the B-B line that is the center line extending in a direction (Y axis direction) in which the lead electrode 12A and the lead electrode 12B are arranged side by side.

The anchor column 11H is a columnar resin body surrounded by the facing hollowed portions s4 and t4 provided in the protruding sides s3 and the enclosing sides t3 of the lead electrodes 12A and 12B. The positions of both the lead electrode 12A and the lead electrode 12B can be fixed by the anchor column 11H disposed in this manner. The number of the anchor columns 11H need only be one pair or more, and a plurality of the anchor columns 11H may be provided symmetrically or asymmetrically.

FIG. 6A illustrates a front surface side of the lead frame 12 (lead electrodes 12A and 12B). An interval (slit width) between the lead electrodes 12A and 12B in the X-axis direction and an interval (slit width) between the lead electrodes 12A and 12B in the Y-axis direction are equal to each other. In addition, the hollowed portions s4 and t4 provided on the adjacent sides s and t of the lead electrode 12A and the lead electrode 12B are disposed to face each other, and the anchor column 11H is formed in the region surrounded by the hollowed portions s4 and t4 by the filled frame resin.

FIG. 6B illustrates the back surface side of the lead frame 12. As illustrated in the drawing, the protrusion As of the lead electrode 12A and the enclosing portion Bt of the lead electrode 12B have respective step portions 12M and 12N formed by thinning the thickness of the lead frame 12 along the peripheral edge (the entire slit 39). A groove portion in which the back surface side is recessed is formed by the step portions 12M and 12N, and the groove portion (12M and 12N) is also filled with the frame resin (see FIG. 4).

As illustrated in FIG. 7, in a portion in which the circular anchor column 11H including the hollowed portions s4 and t4 is formed, a line width (gap in the X-axis direction) of the straight line portion is denoted by H1, and a length from the straight line to the circular end portion is denoted by H2 and H3. In this case, it is preferable that a relationship of H1≤H2˜H3 is established. As a result, the lead electrode 12A and the lead electrode 12B are integrated with each other via the anchor column 11H by the filled frame resin, and misalignment can be prevented.

Specifically, in a case where a pulling force is applied to the lead electrode 12A in the longitudinal direction (Y-axis direction), the same force is also applied to the lead electrode 12B via the anchor column 11H. That is, even in a case where a force is applied to one lead electrode (12A or 12B), a force is also applied to the other lead electrode (12A or 12B), so that the one lead electrode is not easily pulled out. In addition, since the anchor column 11H is integrated with both lead electrodes (12A and 12B), only one lead electrode (12A or 12B) is not pulled out. In a case where the anchor column 11H is circular, the force acting from the lead electrode (12A or 12B) on the anchor column 11H is dispersed, which is suitable.

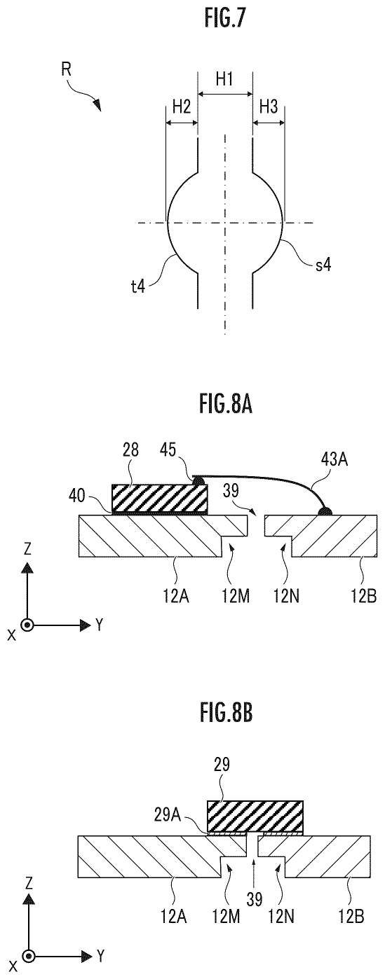

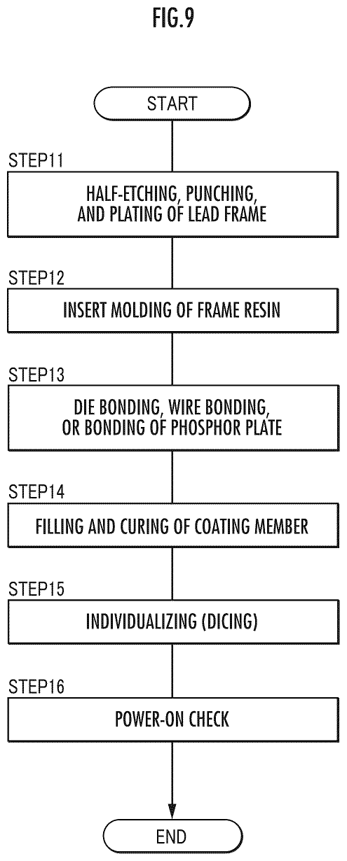

FIG. 8A is a cross-sectional view of the vicinity of the slit 39 along the B-B line (one-dot chain line) of the lead frame 12 of FIG. 6A. The LED 28 is mounted on the lead electrode 12A via a joining member 40. The LED 28 is connected to the lead electrode 12B via a bump 45 provided on the p-electrode of the LED 28 by using two bonding wires 43A (see FIG. 3). The lead electrodes 12A and 12B are a cathode and an anode of the light-emitting device 10, and an application voltage is supplied from the outside of the light-emitting device 10.

In addition, FIG. 8B illustrates a cross-sectional view of a case in which the light emitting element is a flip chip (modified example). As illustrated in the drawing, an LED 29 is mounted to extend over the lead electrode 12A and the lead electrode 12B via a lower electrode 29A. The sizes and depths of the step portions 12M and 12N are the same as the sizes and depths of the light-emitting device 10 in FIG. 8A, but the width of the slit 39 is narrower. In a case of the flip-chip, the position misalignment between the lead electrode 12A and the lead electrode 12B can be prevented by the aspect in which the anchor column 11H is provided as described above, so that the breakage of the bonding portion can be prevented.

### (Manufacturing Method)

Hereinafter, a manufacturing method of the light-emitting device 10 will be described in detail with reference to a flowchart and the drawings.

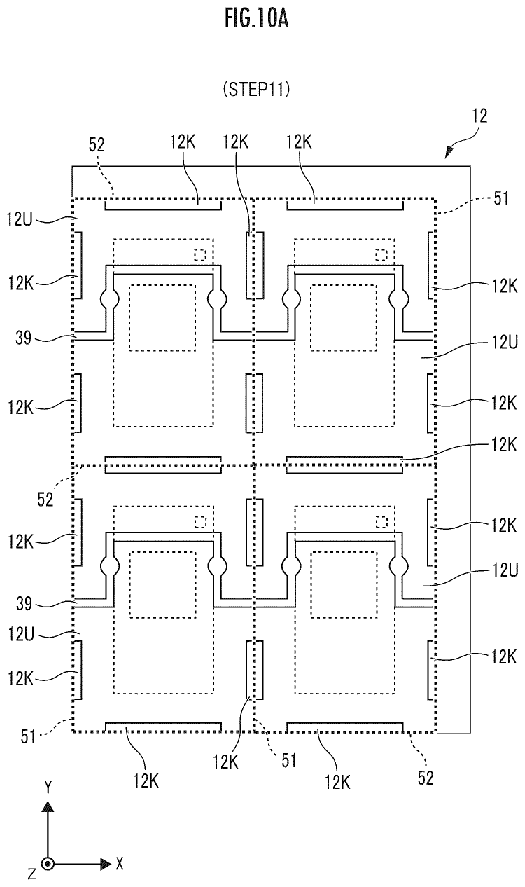

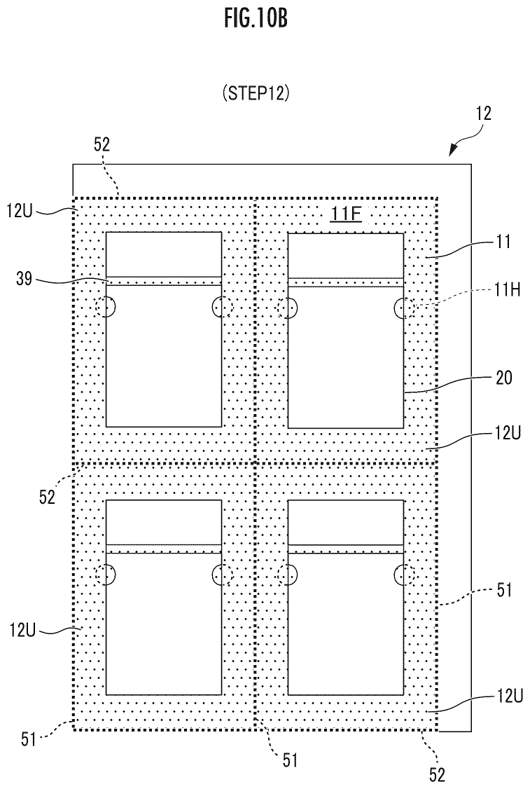

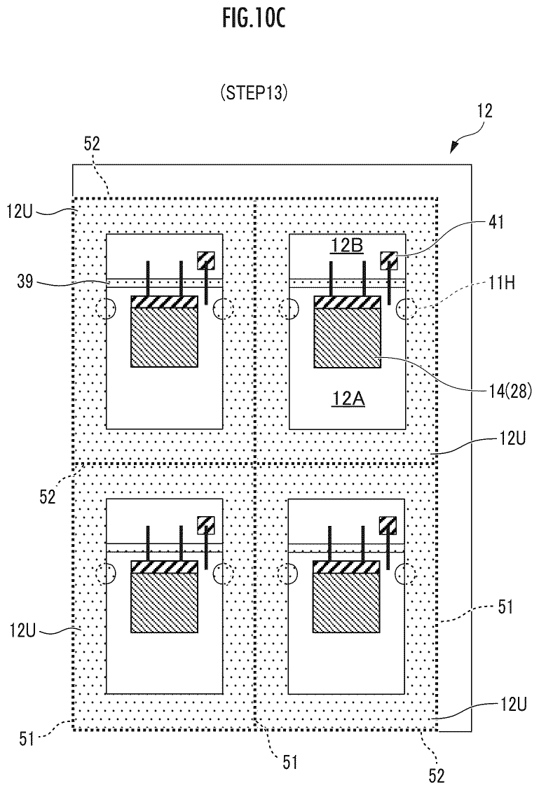

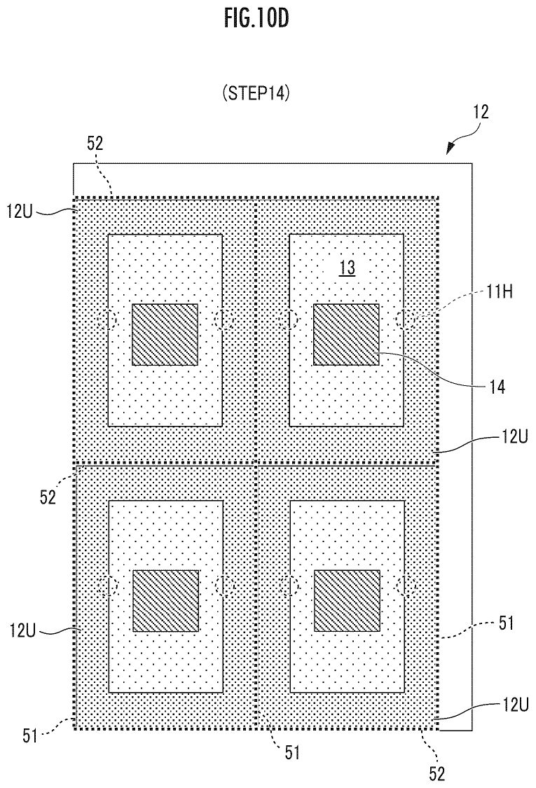

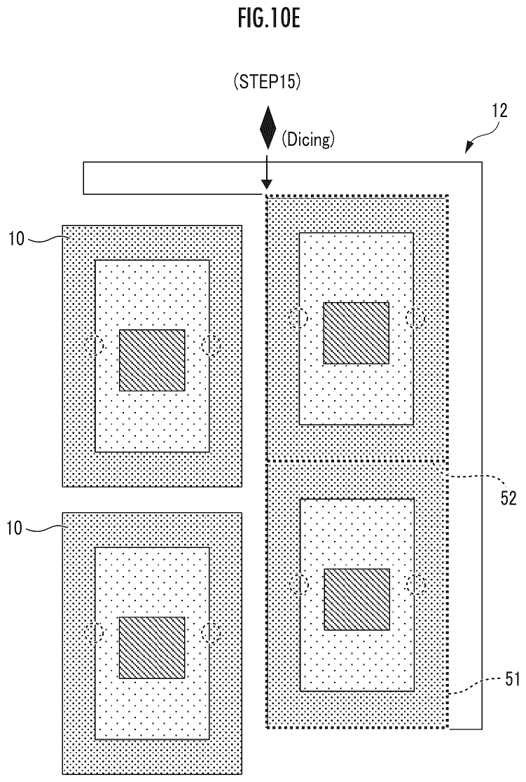

FIG. 9 is a flowchart illustrating the manufacturing method of the light-emitting device 10. In addition, FIGS. 10A to 10E are top views illustrating the respective steps. Hereinafter, the manufacturing method of the light-emitting device 10 will be described with reference to FIGS. 10A to 10E.

Step S11 is a half-etching, punching, and plating step of the lead frame. As illustrated in FIG. 10A, the lead frame 12 has a plurality of unit sections 12U arranged in a matrix shape. More specifically, the lead frame 12 is divided into a plurality of unit sections 12U by vertical dicing lines 51 and horizontal dicing lines 52 (both illustrated by broken lines) that are arranged at equal intervals in the X-axis direction and the Y-axis direction. Each unit section 12U corresponds to the lead frame 12 of one light-emitting device 10.

In such a lead frame 12, first, a back surface side of the copper plate serving as the lead frame 12 is half-etched to be scraped to have a predetermined width and depth, whereby the step portions 12M and 12N are formed (see FIG. 6B or FIG. 8A). Next, the punching (pressing) is performed to form the slit 39 and a notch portion 12K. By providing a large number of notch portions 12K in the lead frame 12, a step of individualizing (dicing) the lead frame 12, which will be described later, is facilitated. Thereafter, Ni/Au plating is performed on the front surface and the back surface of the lead frame 12.

Step S12 is an insert molding step of the frame resin. As illustrated in FIG. 10B, a molded resin body 11F is formed by performing the insert molding of the frame resin. More specifically, the lead frame 12 is sandwiched between an upper mold and a lower mold, and a thermosetting resin consisting of a silicone resin containing titanium oxide particles is injected, thereby forming the molded resin body 11F. The molded resin body 11F fills the opening portion 20, the slit 39, and the inside of the notch portion 12K of the inner region of the frame 11, corresponding to each of the unit sections 12U.

Step S13 is a step of die bonding, wire bonding, or bonding of a phosphor plate. As illustrated in FIG. 10C, the LED 28 (present on the lower surface side of the phosphor plate 14) is mounted (die-bonded) on the lead electrode 12A using the joining member 40 (in the present embodiment, a gold-tin (AuSn) alloy). Similarly, the protective element 41 is also bonded to the lead electrode 12B. Thereafter, the lead electrode 12B and the lead electrode 12A provided on the upper surfaces of the LED 28 and the protective element 41 are connected to each other by wire bonding using a gold wire.

Next, the phosphor plate 14 is bonded to the LED 28 using a transparent silicone adhesive, and the LED 28, the phosphor plate 14, and the protective element 41 are placed inside the opening portion 20.

Step S14 is a filling and curing step of the coating member. As illustrated in FIG. 10D, the opening portion 20 of the frame 11 is coated with a light-reflective silicone resin containing titanium oxide particles such that the surface of the phosphor plate 14 is exposed, and the coating member 13 is formed by heating and curing.

Step S15 is an individualizing (dicing) step. As illustrated in FIG. 10E, dicing is performed along the vertical dicing line 51 and the horizontal dicing line 52. That is, the light-emitting devices 10 are separated from each other by cutting the molded resin body 11F.

Step S16 is a power-on check step. Finally, an electrical characteristic test such as a power-on check of each light-emitting device 10 is performed. The manufacturing of the light-emitting device 10 is completed by the above steps.

### Second Embodiment

Next, a light-emitting device 60 according to a second embodiment of the present invention is described. The same configurations as the configurations of the first embodiment are denoted by the same reference numerals. Since the structure and manufacturing method of the second embodiment are substantially the same as the structure and manufacturing method of the first embodiment, only different parts will be described.

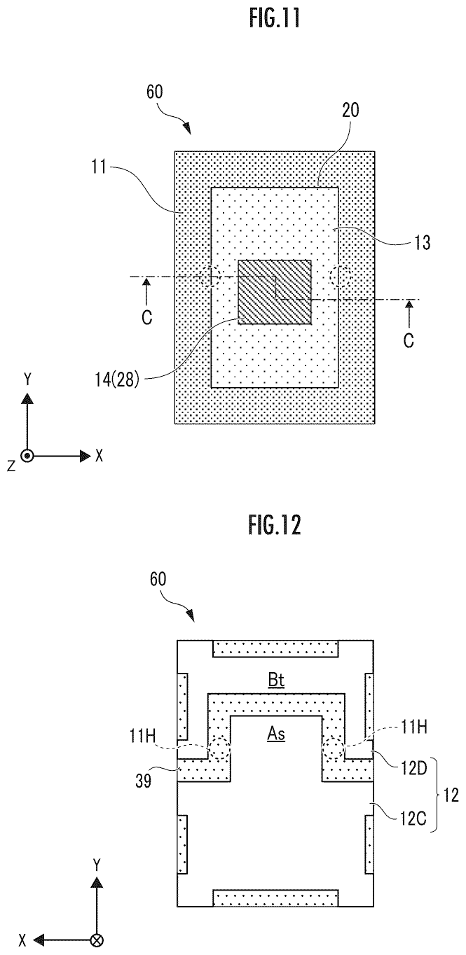

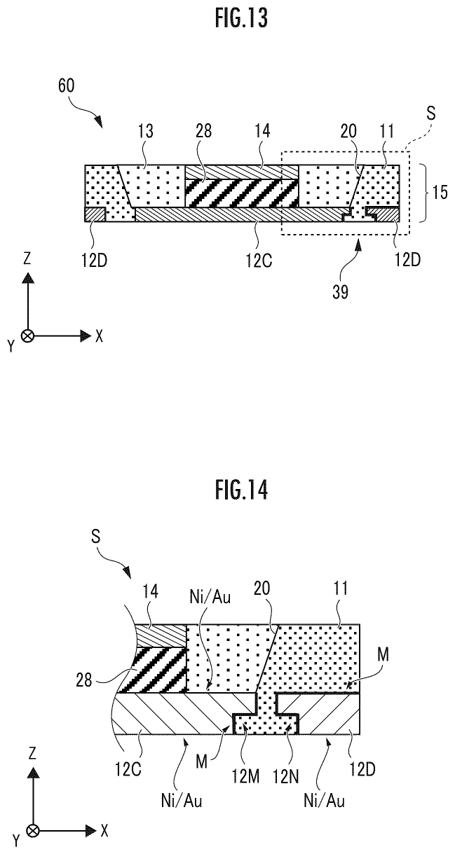

FIG. 11 is a top view of the light-emitting device 60. In addition, FIG. 12 is a back view (lower view) of the light-emitting device 60, and FIG. 13 is a cross-sectional view (free cross-sectional view) of the light-emitting device 60 taken along line C-C (one-dot chain line) in FIG. 11.

The light-emitting device 60 according to the second embodiment is different from the light-emitting device 10 according to the first embodiment only in that the structures of boundary layers of the portions of a lead electrode 12C (first electrode) and a lead electrode 12D (second electrode) in contact with the frame 11 are different. Therefore, a visible portion of FIG. 11, which is the top view, and a visible portion of FIG. 12, which is the back view, and the arrangement of the LED 28, the protective element 41, and the phosphor plate 14 placed on the opening portion 20 or the like are also the same as those of the first embodiment.

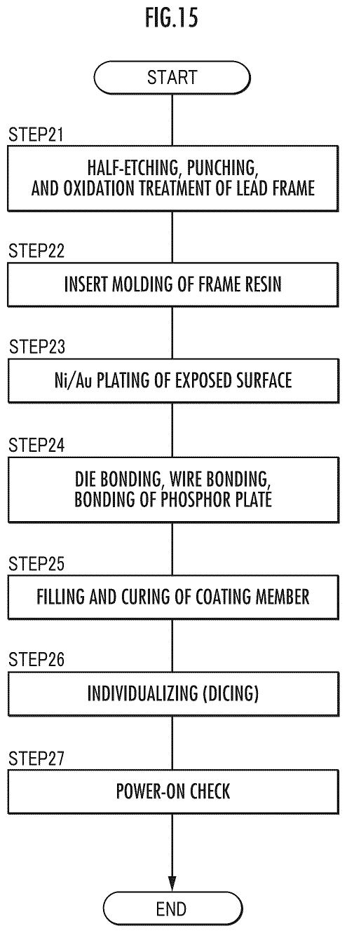

FIG. 14 is an enlarged view of a region S of FIG. 13.

Similarly to the lead electrodes 12A and 12B (see FIGS. 4 and 6B), the protrusion As of the lead electrode 12C and the enclosing portion Bt of the lead electrode 12D have the step portions 12M and 12N obtained by the half-etching along the peripheral edge (the entire slit 39). In addition, a groove portion (12M and 12N) including the step portions 12M and 12N is formed.

In addition, in the light-emitting device 60 according to the second embodiment, a metal oxide film M which is a copper oxide film is provided at an interface between the frame resin and the lead frame 12. The metal oxide film M is a continuous oxide film from the copper material which is the core material of the lead electrodes 12C and 12D, and is integrated. As a result, in addition to the fixing effect of the lead frame 12 by the anchor column 11H, the adhesive force between the lead frame 12 and the frame resin is improved, and the lead frame 12 and the frame resin are integrated to form the substrate 15 having high strength against the external stress.

### (Manufacturing Method)

Hereinafter, a manufacturing method of the light-emitting device 60 will be described in detail with reference to a flowchart.

FIG. 15 is a flowchart illustrating a manufacturing method of the light-emitting device 60.

Step S21 is a half-etching, punching, and oxidation treatment step of the lead frame. First, a back surface of the copper plate to be the lead frame 12 is half-etched to be scraped to have a predetermined width and depth, thereby forming the step portions 12M and 12N (see FIG. 14). Next, the punching (pressing) is performed by a press molding machine to form the slit 39 and the notch portion 12K.

Next, the surface (upper surface, lower surface, and side surface) of the punched lead frame 12 is subjected to an oxidation treatment. Specifically, the surface of the lead frame 12 from which the punching has been performed is oxidized in an oxygen and nitrogen gas atmosphere (150° C., 5 minutes) to form the metal oxide film M.

Step S22 is an insert molding step of the frame resin. This step is the same as the insert molding step of the frame resin in Step S12 of the first embodiment, except that the lead frame 12 on which the metal oxide film M is formed is used.

Step S23 is a Ni/Au plating step of the exposed surface. The metal oxide film M consisting of the copper oxide on the surface of the lead frame 12 exposed from the frame 11 of the substrate 15 formed in Step S22 is removed by the acid aqueous solution. Subsequently, an Ni/Au layer is formed on a portion of the removed lead frame 12 by electroplating with an electric field. The metal oxide film M present at the interface between the frame resin and the lead frame 12 remains as it is (see FIG. 14).

Subsequently, the following steps are executed, but the steps are the same as the steps (FIG. 9: Steps S13 to S16) of the manufacturing method according to the first embodiment, and thus the detailed description thereof will be omitted.

Step S24: step of die bonding, wire bonding, and bonding of the phosphor plate

Step S25: filling and curing step of coating member

Step S26: individualizing (dicing) step

Step S27: power-on check step

The manufacturing of the light-emitting device 60 is completed by the above-described steps. As described above, according to the present invention, it is possible to provide a manufacturing method of a light-emitting device in which a position misalignment of a lead electrode can be prevented during solder mounting or the like.

Although the embodiment of the present invention has been described, the present invention is not limited to the above-described embodiment and modified embodiment, and can be carried out in various aspects within the scope not departing from the gist thereof.

For example, although the circular anchor column 11H is illustrated, the anchor column 11H may have an arc shape such as an elliptical column (an oblong column), or a rectangular column or polygonal column shape such as a square column or a hexagonal column. A plurality of the anchor columns 11H can also be provided in the slit 39 portions in the longitudinal direction (Y direction). In addition, the thickness of the lead frame 12, the numerical value or the like of the treatment temperature or the like in the manufacturing method, and the like are merely examples, and can be appropriately changed and applied.

### DESCRIPTION OF REFERENCE NUMERALS

10: light-emitting device
11: frame
11H: anchor column
12: lead frame
12A, 12B, 12C, 12D: lead electrode
12K: notch portion
12M, 12N: step portion
12U: unit section
13: coating member
14: phosphor plate
15: substrate
20: opening portion
28, 29: LED
29A: lower electrode
39: slit
40: joining member
41: protective element
43A: bonding wire
45: bump
51: vertical dicing line
52: horizontal dicing line

1. A semiconductor light-emitting device comprising:
a plurality of plate-shaped lead electrodes arranged side by side in a rectangular shape to be separated with a predetermined interval from each other;
a frame consisting of a resin configured to cover an outer portion of the plurality of lead electrodes and a separation portion between the plurality of lead electrodes and having an opening portion that exposes the plurality of lead electrodes; and
a light emitting element mounted on the plurality of lead electrodes exposed from the opening portion,
wherein:
the plurality of lead electrodes includes one lead electrode having a first adjacent side with a protruding portion provided in a portion separated from each other with the predetermined interval, and an other lead electrode having a second adjacent side with a recessed portion into which the protruding portion of the one lead electrode is fitted,
the one lead electrode and the other lead electrode have a nested structure in which the protruding portion of the one lead electrode is fitted into the recessed portion of the other lead electrode,
a hollowed portion having a predetermined shape extending over both the adjacent sides is provided in each of the first adjacent side and the second adjacent side, and
a region surrounded by the hollowed portion of each of the one lead electrode and the other lead electrode is filled with a part of the resin forming the frame.

2. The semiconductor light-emitting device according to claim 1, wherein the hollowed portions are each provided at a position symmetrical with respect to a center line of the frame extending in an arrangement direction of the one lead electrode and the other lead electrode.

3. The semiconductor light-emitting device according to claim 1, wherein the one lead electrode and the other lead electrode have a step portion formed along the first adjacent side and the second adjacent side on a back surface side, and the step portion is filled with the resin.

4. The semiconductor light-emitting device according to claim 1, further comprising a coating member filling the opening portion to cover a periphery of the light emitting element.

5. The semiconductor light-emitting device according to claim 1, wherein the light emitting element includes a light emitting diode and an optical member placed on the light emitting diode.

6. The semiconductor light-emitting device according to claim 3, wherein an interface between the step portion and the resin is coated with a metal oxide film.

7. The semiconductor light-emitting device according to claim 1, wherein the light emitting element is placed to extend over both the one lead electrode and the other lead electrode.

8. The semiconductor light-emitting device according to claim 1, wherein the region surrounded by the hollowed portion has a circular, elliptical, or rectangular shape.
